(19) United States
(12) Patent Application Publication
(10) Pub. No.: US 2016/0013264 A1
(43) Pub. Date: Jan. 14, 2016

(54) ELECTRO-OPTICAL DEVICE, ELECTRONIC APPARATUS, AND DRIVE CIRCUIT

(71) Applicant: SEIKO EPSON CORPORATION, Shinjuku-ku, Tokyo (JP)

(72) Inventor: Masahito Yoshii, Chitose-shi (JP)

(21) Appl. No.: 14/770,775

(22) PCT Filed: Mar. 3, 2014
(86) PCT No.: PCT/JP2014/001120

§ 371 Date: Aug. 26, 2015

(30) Foreign Application Priority Data
Mar. 6, 2013 (JP) 2013-043795

(51) Int. Cl. H01L 29/06; G02F 1/1368; H01L 29/78; G02F 1/1362

(52) U.S. Cl. CPC H01L 29/0615; G02F 1/136204; G02F 1/1368; H01L 29/7833

(57) ABSTRACT

There are provided an electro-optical device that includes a peripheral circuit which is resistant against static electricity and an electronic apparatus that includes the electro-optical device. A liquid crystal device that is used as an electro-optical device includes a pixel circuit, and a peripheral circuit that drives and controls the pixel circuit, and a data line drive circuit 101 that is used as the peripheral circuit includes resistors Rs that are added in series to gates, sources, and drains of transistors 121, 123, 125, and 127 which are included in a first stage circuit and a final stage circuit of the data line drive circuit 101.

### BACKGROUND

1. Technical Field

The present invention relates to an electro-optical device and an electronic apparatus. Specifically, the invention relates to measure against electrostatic breakdown in an electro-optical device. Furthermore, the invention relates to a drive circuit or the like.

2. Related Art

An electro-optical device that includes a circuit substrate to which measure against electrostatic breakdown are provided during manufacture and use is known (for example, see JP-A-2004-152901).

A circuit substrate described in JP-A-2004-152901 includes a plurality of terminals formed on a substrate and a resistor formed between terminals adjacent to each other, and has a configuration in which a resistor connected to an analog terminal out of the plurality of terminals has a resistance value greater than that of a resistor connected to a digital terminal. According to this, electrostatic protection can be achieved in all the terminals by the resistor, and the occurrence of cross talk in the analog terminals can be eliminated.

However, in order to introduce a resistor that is used for countermeasure against static electricity, it is necessary to modify the wiring pattern of the related art. A problem is that, if the wiring pattern of the related art is complicated or has a high definition, it is difficult to modify the wiring pattern.

The invention is intended to solve at least a portion of the problem described above, and can be realized as the following forms or application examples.

### SUMMARY

### Application Example 1

According to this application example, there is provided an electro-optical device including a pixel circuit; and a peripheral circuit that drives and controls the pixel circuit. The peripheral circuit includes a resistor that is added to a transistor which is included in at least one of a first stage circuit and a final stage circuit of the peripheral circuit.

Since a wire (for example, a power supply wire, a constant potential wire or the like) with a wider area than that of the pixel circuit is connected to the peripheral circuit that drives and controls the pixel circuit, in relation to the wiring layout, static electricity is easily attracted because the wire becomes an antenna. That is, electrostatic breakdown easily occurs in the peripheral circuit.

According to the present application example, the resistor that is added to the transistor which is included in at least one of the first stage circuit and the final stage circuit of the peripheral circuit is provided, and thus, even if static electricity invades the peripheral circuit, the static electricity can be consumed by the resistor. That is, it is possible to provide an electro-optical device that includes a peripheral circuit which is resistant against static electricity.

### Application Example 2

In the electro-optical device according to the application example, the resistor may be added in series to at least one of positions between a gate of the transistor and a gate wire, between a source of the transistor and a source wire, and between a drain of the transistor and a drain wire.

According to the configuration, it is possible to suppress the breakdown of the transistor of the peripheral circuit due to static electricity.

### Application Example 3

In the electro-optical device according to the application example, the resistor may be a contact section that is provided at least at one of positions between a gate of the transistor and a gate wire, between a source of the transistor and a source wire, and between a drain of the transistor and a drain wire, and the contact section may have a smaller size than that of a transistor that is included in a circuit other than the first stage circuit and the final stage circuit of the peripheral circuit.

### Application Example 4

In the electro-optical device according to the application example, the resistor may be a contact section that is provided at least at one of positions between a gate of the transistor and a gate wire, between a source of the transistor and a source wire, and between a drain of the transistor and a drain wire, and the number of the contact sections may be smaller than the number of transistors that is included in a circuit other than the first stage circuit and the final stage circuit of the peripheral circuit.

According to the configuration, it is possible to suppress the breakdown of the transistor of the peripheral circuit due to the static electricity. In addition, the resistor for countermeasure against static electricity functions by changing the size of a contact section or the number of contact sections, a new resistor for countermeasure against static electricity may not be added, and the wiring pattern of the peripheral circuit may not be complicated.

### Application Example 5

In the electro-optical device according to the application example, the transistor may include a semiconductor layer that includes a channel region and a lightly doped drain (LDD) region that is in contact with the channel region, and the resistor may be the LDD region, and may be longer in LDD length than an LDD region of a transistor that is included in a circuit other than the first stage circuit and the final stage circuit of the peripheral circuit.

### Application Example 6

In the electro-optical device according to the application example, the transistor may include a semiconductor layer that includes a channel region and a lightly doped drain (LDD) region that is in contact with the channel region, and the resistor may be the LDD region, and may be smaller in a dose amount of impurity ions than an LDD region of a transistor that is included in a circuit other than the first stage circuit and the final stage circuit of the peripheral circuit.

According to the configuration, the size of the LDD region becomes large and a dose amount of impurity ions in the LDD regions becomes small, and thereby the LDD region functions as the resistor for countermeasure against static electricity. Thus, it is possible to suppress the break down of the transistor of the peripheral circuit due to the static electricity. In addition, since the LDD region is used as the resistor for countermeasure against static electricity, a new resistor for countermeasure against static electricity may not be added, and the wiring pattern of the peripheral circuit may not be complicated.

### Application Example 7

According to this application example, there is provided an electronic apparatus including the electro-optical device according to the application example.

According to the present application example, since an electro-optical device to which measure against electrostatic breakdown are provided during manufacture and use is provided, it is possible to provide an electronic apparatus which is excellent in cost performance and which is more resistant against static electricity than that of the related art.

### BRIEF DESCRIPTION OF THE DRAWINGS

FIG. 1(a) is a schematic plan view illustrating a configuration of a liquid crystal device, and FIG. 1(b) is a schematic sectional view taken along a line H-H′ of the liquid crystal device illustrated in FIG. 1(a).

FIG. 2 is an equivalent circuit diagram illustrating an electrical configuration of a liquid crystal device.

FIG. 3 is a logic circuit diagram of a data line drive circuit.

FIG. 4 is a circuit diagram illustrating an example of a data line drive circuit.

FIG. 5(a) is a schematic plan view illustrating a configuration of a transistor of a first stage circuit of Example 1, and FIG. 5(b) is a schematic plan view illustrating a configuration of a transistor of a second stage circuit of Example 1.

FIG. 6(a) is a schematic plan view illustrating a configuration of a transistor of a first stage circuit of Example 2, and FIG. 6(b) is a schematic plan view illustrating a configuration of a transistor of a second stage circuit of Example 2.

FIG. 7(a) is a schematic plan view illustrating a configuration of a transistor of a first stage circuit of Example 3, and FIG. 7(b) is a schematic plan view illustrating a configuration of a transistor of a second stage circuit of Example 3.

FIG. 8 is a schematic diagram illustrating a configuration of a projection type display device.

### DESCRIPTION OF EXEMPLARY EMBODIMENTS

Hereinafter, embodiments that specify the invention will be described in accordance with the drawings. The drawings to be used are illustrated in an appropriated expanded or contracted manner, such that portions to be described are in a recognizable state.

In a case in which it is described that a member is disposed, for example, “on a substrate” in the following embodiments, the case represents a case in which the member is disposed so as to be in contact with the upper portion of the substrate, a case in which the member is disposed over the substrate across a configuration element, a case in which a portion of the member is disposed so as to be in contact with the upper portion of the substrate and a portion of the member is disposed over the upper portion of the substrate across a configuration element, or the like.

### First Embodiment

In the present embodiment, an active matrix type liquid crystal device that includes a thin film transistor (TFT) as a switching element of a pixel will be described as an example. The liquid crystal device can be appropriately used as an optical modulation element (liquid crystal light valve) of a projection type display device (liquid crystal projector) to be described below, for example.

### <Liquid Crystal Device>

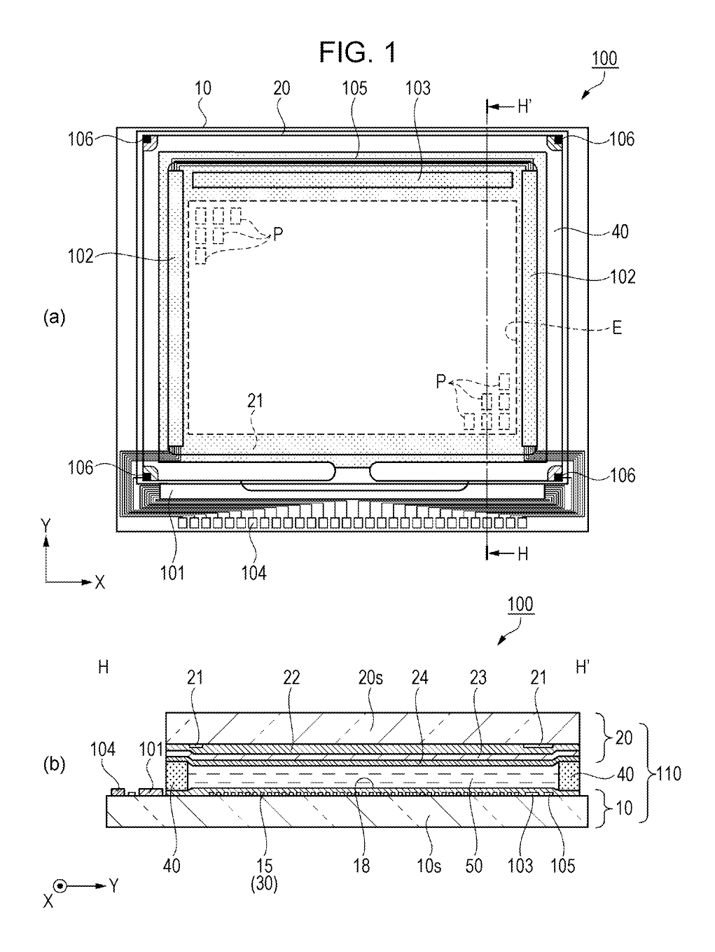

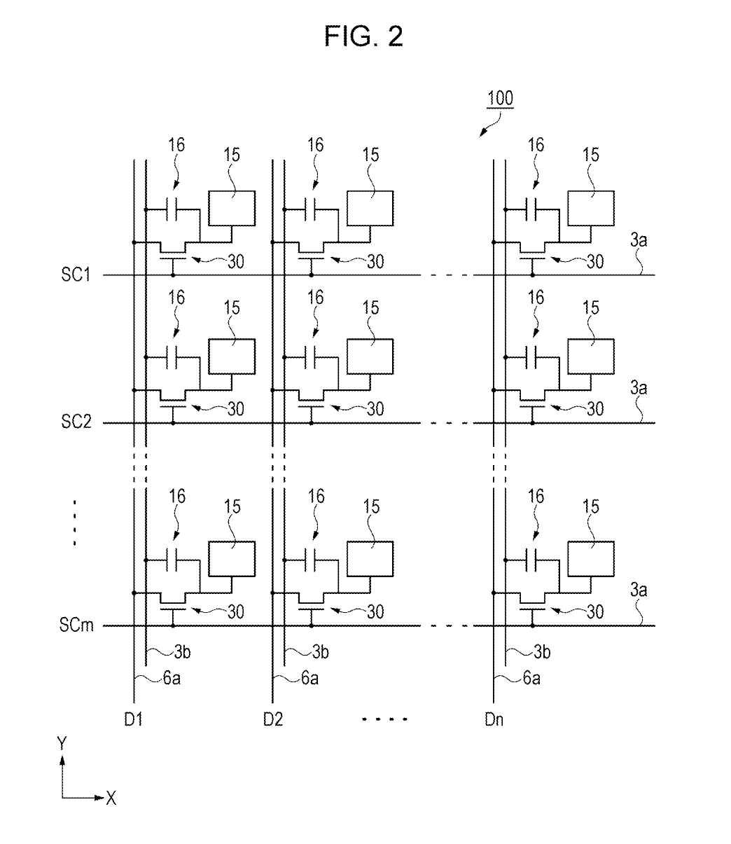

To begin with, a liquid crystal device that is used as an electro-optical device of the present embodiment will be described with reference to FIG. 1 and FIG. 2. FIG. 1(a) is a schematic plan view illustrating a configuration of a liquid crystal device, and FIG. 1(b) is a schematic sectional view taken along a line H-H′ of the liquid crystal device illustrated in FIG. 1(a). FIG. 2 is an equivalent circuit diagram illustrating an electrical configuration of a liquid crystal device.

As illustrated in FIGS. 1(a) and 1(b), the liquid crystal device 100 that is used as an electro-optical device of the present embodiment includes an element substrate 10 and a counter substrate 20 that oppose each other, and a liquid crystal layer 50 that is interposed between such a pair of substrates. A base member 10s of the element substrate 10 and a base member 20s of the counter substrate 20 respectively use a transparent material, such as a quartz substrate or a glass substrate.

The element substrate 10 is larger than the counter substrate 20, both substrates are bonded with an interval therebetween via a sealing material 40 that is disposed along an outer edge of the counter substrate 20, and a liquid crystal layer 50 is configured by sealing liquid crystal having a positive or negative dielectric anisotropy in the interval. An adhesive such as a heat-curable or ultraviolet curable epoxy resin is applied to the sealing material 40. A spacer (not illustrated) for constantly retaining the interval between a pair of substrates is mixed into the sealing material 40.

A pixel area E which includes a plurality of pixels P that is arranged in a matrix in the inside of the sealing material 40 is provided. In addition, a parting section 21 that surrounds the pixel area E is provided between the sealing material 40 and the pixel area E. The parting section 21 is formed from, for example, a metal with a light shielding property, a metal oxide, or the like. The pixel area E may include dummy pixels that are disposed so as to surround the plurality of pixels P, in addition to the plurality of pixels P contributing to the display. In addition, while not illustrated in FIG. 1, a light shielding section (block matrix; BM) that respectively separates the plurality of pixels P in a planar manner in the pixel area E is provided in the counter substrate 20.

A terminal section in which a plurality of external connection terminals 104 is arranged is provided in the element substrate 10. A data line drive circuit 101 is provided between a first side portion and the sealing material 40, along the terminal section. In addition, a test circuit 103 is provided between the sealing material 40 and the pixel area E, along a second side portion opposite to the first side portion. Furthermore, scan line drive circuits 102 are provided between the sealing material 40 and the pixel area E, along third and fourth side portions that are orthogonal to the first side portion and oppose each other. A plurality of wires 105 is provided which connects together the two scan line drive circuits 102 between the sealing material 40 of the second side portion and the test circuit 103.

The wires that are connected to the data line drive circuit 101 and the scan line drive circuit 102 are connected to a plurality of external connection terminals 104 that are arranged along the first side portion. Thereafter, it will be described that a direction along the first side portion is referred to as an X direction, and a direction along the third side portion is referred to as a Y direction. Disposition of the test circuit 103 is not limited to this, and the test circuit 103 may be provided in a position along an inner side of the sealing material 40 between the data line drive circuit 101 and the pixel area E.

As illustrated in FIG. 1(b), light transmitting pixel electrodes 15 and thin film transistors (hereinafter, referred to as TFT) 30 which are switching elements, that are provided in each pixel P, signal lines, and a counter film 18 that covers those are formed on a surface of the liquid crystal layer 50 side of the element substrate 10. In addition, a light shielding structure is employed which prevents a switching operation from being unstable when light is incident on a semiconductor layer of the TFT 30. The element substrate 10 includes the base member 10s, the light transmitting pixel electrodes 15 that are formed on the base member 10s, the TFT 30, the signal wires, and the counter film 18.

The counter substrate 20 that is disposed so as to oppose the element substrate 10 includes the base member 20s, the parting section 21 that is formed on the base member 20s, a planarization layer 22 that is formed so as to cover those, a common electrode 23 that covers the planarization layer 22 and is provided across at least a portion of the pixel area E, and a counter film 24 that covers the common electrode 23.

As illustrated in FIG. 1(a), the parting section 21 surrounds the pixel area E, and is provided in a position that overlaps the scan line drive circuit 102 and the test circuit 103 in a planar manner. According to this, the parting section 21 performs a function of shielding light that is incident on the circuits from the counter substrate 20 side and prevents the circuits from malfunctioning due to the light. In addition, the parting section 21 shields unnecessary stray light so as to not be incident on the pixel area E, and ensures high contrast in the display of the pixel area E.

The planarization layer 22 is formed from an inorganic material such as silicon oxide, and is provided so as to cover the parting section 21 with light transmissivity. A method of forming a film by using, for example, a plasma CVD method or the like is used as a method of forming the planarization layer 22.

The common electrode 23 is formed from a transparent conductive film such as indium tin oxide (ITO), covers the planarization layer 22, and is electrically connected to wires on the element substrate 10 side by vertical connection sections 106 that are provided on four corners of the counter substrate 20, as illustrated in FIG. 1(a).

The counter film 18 that covers the pixel electrode 15 and the counter film 24 that covers the common electrode 23 are selected based on an optical design of the liquid crystal device 100. For example, a film configured by an organic material such as polyimide is formed, and an organic counter film is formed in which substantially horizontal orientation processing is performed with respect to liquid crystal molecules with a positive dielectric anisotropy by rubbing a surface of the film. Alternatively, a film configured by an inorganic material such as SiOx (silicon oxide) is formed by using a vapor phase growth method, and an inorganic counter film is formed which is substantially and vertically oriented with respect to liquid crystal molecules with a negative dielectric anisotropy.

The liquid crystal device 100 is a transmission type, and employs an optical design of a normally white mode in which a transmission rate of the pixel P becomes maximum in a state in which a voltage is not applied, or a normally black mode in which a transmission rate of the pixel P becomes the minimum in a state in which a voltage is not applied. Polarization elements are respectively disposed according to an optical design on the incident side and exit side of light of a liquid crystal panel 110 that includes the element substrate 10 and the counter substrate 20 and are used.

Next, an electrical configuration of the liquid crystal device 100 will be described with reference to FIG. 2. The liquid crystal device 100 includes a plurality of scan lines 3a and a plurality of data lines 6a that are used as signal wires which are insulated with each other and orthogonal to each other in at least the pixel area E, and capacitor lines 3b that are disposed in parallel along the data lines 6a. A direction in which the scan lines 3a extend is the X direction, and a direction in which the data lines 6a extend is the Y direction.

A pixel electrode 15, a TFT 30, and a storage capacitor 16 are provided in an area that is separated by the scan line 3a, the data line 6a, the capacitor line 3b, and this type of signal lines. A pixel circuit of the pixel P is configured by the pixel electrode 15, the TFT 30, and the capacitor 16.

The scan line 3a is electrically connected to the gate of the TFT 30, and the data line 6a is electrically connected to the source of the TFT 30. The pixel electrode 15 is electrically connected to the drain of the TFT 30.

The data line 6a is connected to the data line drive circuit 101 (refer to FIG. 1), and supplies the pixel P with image signals D1, D2, . . . , and Dn that are supplied from the data line drive circuit 101. The scan line 3a is connected to the scan line drive circuit 102 (refer to FIG. 1), and supplies the pixel P with scan signals SC1, SC2, . . . , and SCm that are supplied from the scan line drive circuit 102.

The image signals D1 to Dn that are supplied from the data line drive circuit 101 to the data lines 6a may be supplied in a line sequence in this sequence, and may be supplied to each group with respect to the plurality of data lines 6a which are adjacent to each other. The scan line drive circuit 102 supplies the scan lines 3a with the scan signals SC1 to SCm in a pulse manner and in a line sequence at a predetermined timing.

The liquid crystal device 100 has a configuration in which the TFT 30 that is a switching element is in an ON state only for a predetermined period by an input of the scan signals SC1 to SCm and thereby the image signals D1 to Dn that are supplied from the data lines 6a are written to the pixel electrodes 15 at predetermined timing. Then, the image signals D1 to Dn with predetermined levels that are written to the liquid crystal layer 50 via the pixel electrodes 15 are retained for a predetermined period between the common electrodes 23 and the pixel electrodes 15 that are disposed in an opposed manner via the liquid crystal layer 50.

In order to prevent the retained image signals D1 to Dn from leaking, a storage capacitor 16 is connected in parallel to a liquid crystal capacitor formed between the pixel electrode 15 and the common electrode 23. The storage capacitor 16 is provided between the drain of the TFT 30 and the capacitor line 3b.

The data lines 6a are connected to the test circuit 103 illustrated in FIG. 1(a), and the test circuit 103 is configured such that operation defects or the like of the liquid crystal device 100 can be confirmed by detecting the image signals during manufacturing processing of the liquid crystal device 100, but this is omitted in the equivalent circuit of FIG. 2.

A peripheral circuit that drives and controls the pixel circuit according to the present embodiment includes the data line drive circuit 101, the scan line drive circuit 102, and the test circuit 103. In addition, the peripheral circuit may include a sampling circuit that samples the image signals and supplies the data lines 6a with sampled signals, and a precharge circuit that supplies the data line 6a with a precharge signal with a predetermined voltage level prior to the image signal.

Next, a countermeasure against static electricity for the peripheral circuit according to the invention will be described by using a circuit configuration of the data line drive circuit 101 of the peripheral circuit as an example.

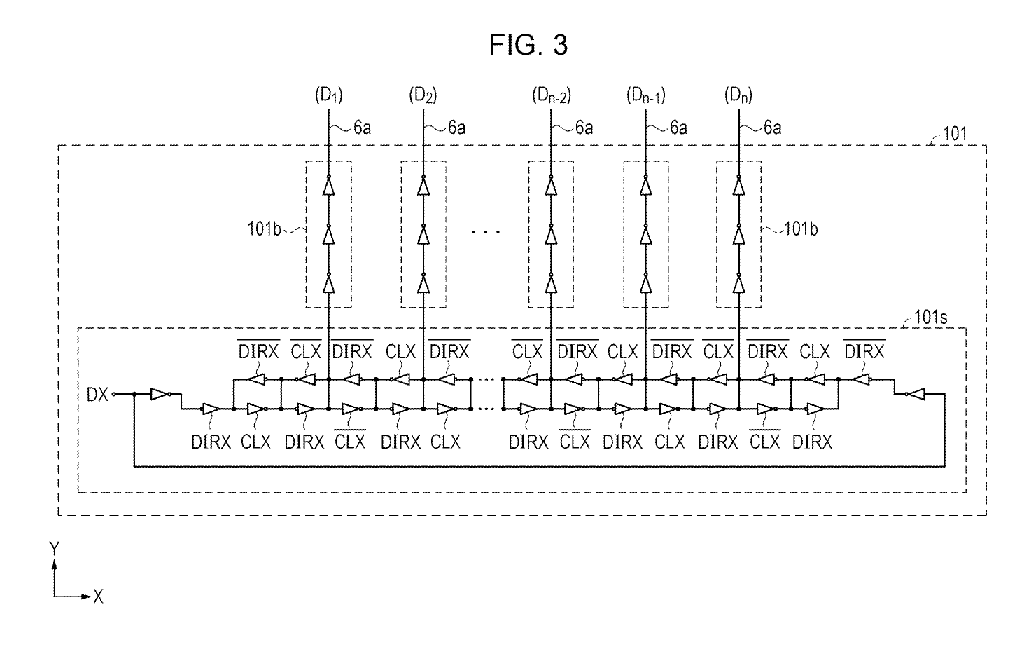

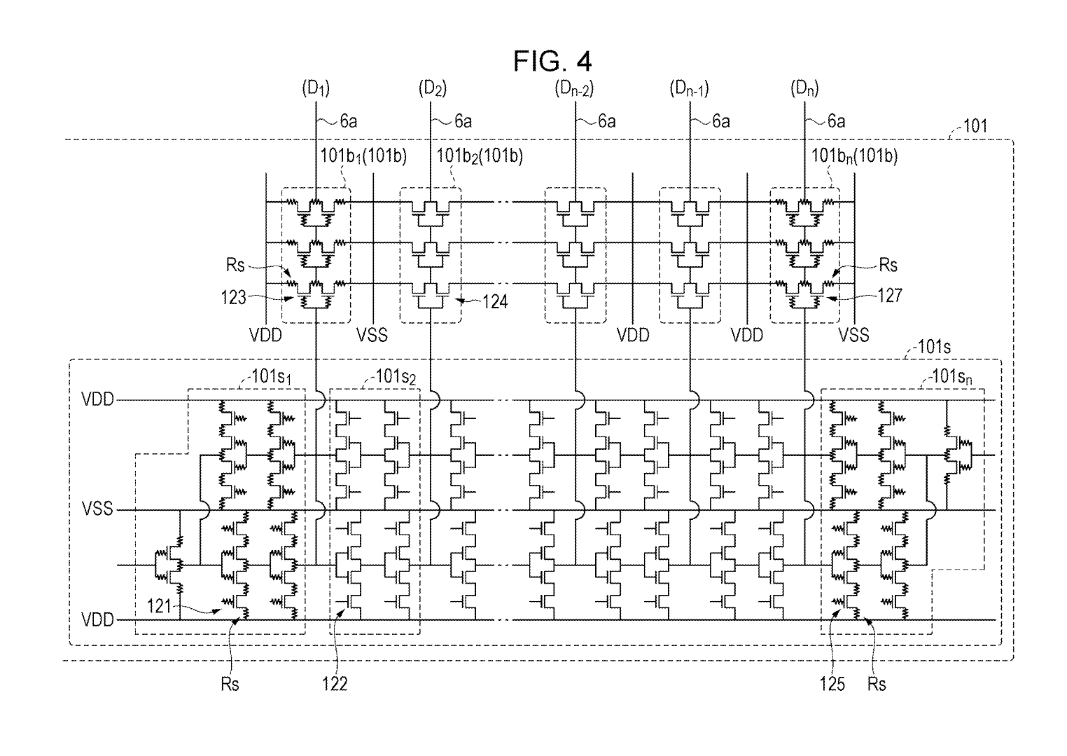

FIG. 3 is a logic circuit diagram of the data line drive circuit, and FIG. 4 is a circuit diagram illustrating an example of the data line drive circuit.

For example, the data line drive circuit 101 that is one of the peripheral circuits is configured to include buffers 101b that are respectively provided in the data lines 6a, and a shift register 101s, as illustrated in FIG. 3. The respective data lines 6a and the shift register 101s are electrically connected to each other via the buffers 101b. The shift register 101s is a circuit for transferring the image signals D1 to Dn described above to a corresponding data line 6a based on a clock signal CLX and a transfer start pulse DX. In addition, the shift register 101s has a configuration in which a write direction of the image signals D1 to Dn with respect to the plurality data lines 6a that are arranged in the X direction can be changed based on a transfer direction control signal DIRX.

A symbol [symbol] denotes an inverted control signal, and a symbol [symbol] denotes an inverted clock signal.

Specifically, as illustrated in FIG. 4, the shift register 101s includes a plurality of inverter circuits that is cascade-connected in correspondence to a write direction of the image signals D1 to Dn to the respective data lines 6a. In order to prevent currents or voltages of the image signals D1 to Dn that are supplied to the data lines 6a from changing, the buffer 101b includes transistors that are connected in series and in parallel to the data lines 6a. The inverter circuit also has a configuration in which transistors are connected in series and in parallel in a transfer direction of the image signals D1 to Dn. Power supply wires through which a reference potential VSS and a drive potential VDD are respectively supplied are connected to the buffer 101b and the shift register 101s.

In a case of the data line drive circuit 101, a first stage circuit of the peripheral circuit according to the invention includes a buffer 101b1 that is connected to the first data line 6a among the plurality of data lines 6a which are arranged in the X direction, and an inverter circuit 101s1 that is connected to the buffer 101b1.

In addition, in a case of the data line drive circuit 101, a final stage circuit of the peripheral circuit according to the invention includes a buffer 101b, that is connected to the nth data line 6a among the plurality of data lines 6a which are arranged in the X direction, and an inverter circuit 101s, that is connected to the buffer 101bₙ.

In relation to the wiring layout of the element substrate 10, the power supply wire that is connected to both of the first stage circuit and the final stage circuit has a large area for suppressing a voltage drop due to a wire resistance, compared to the power supply wire in the inside of the peripheral circuit. Hence, the power supply wire that is connected to the first stage circuit and the final stage circuit acts as an antenna, and thereby static electricity is easily attracted to the peripheral circuit.

Thus, in the present embodiment, the resistors Rs that are used for measure against electrostatic breakdown are added to the transistors that are respectively included in the buffer 101b₁ and the inverter circuit 101s₁ that are used as the first stage circuit, and the buffer 101bₙ and the inverter circuit 101sₙ that are used as the final stage circuit.

Specifically, the resistors Rs are added in series to each of the gates, sources, and drains of all transistors 121 that are included in the inverter circuit 101s¹ of the first stage circuit. In addition, the resistors Rs are added in series to each of the gates, sources, and drains of all transistors 123 that are included in the buffer 101b₁ of the first stage circuit.

The resistors Rs are added in series to each of the gates, sources, and drains of all transistors 125 that are included in the inverter circuit 101sₙ of the final stage circuit. In addition, the resistors Rs are added in series to each of the gates, sources, and drains of all transistors 127 that are included in the buffer 101bₙ of the final stage circuit.

The resistors Rs are not added to circuits other than the first stage circuit and the final stage circuit, for example, each of the gates, sources, and drains of all transistors 122 that are included in the inverter circuit 101s₂ of the second stage circuit. In addition, the resistors Rs are not added to each of the gates, sources, and drains of all transistors 124 that are included in the buffer 101b₂ of the second stage circuit.

In the data line drive circuit 101 that is the peripheral circuit according to the present embodiment, the power supply wires through which a reference potential VSS and a drive potential VDD are supplied are connected to both of the first stage circuit and the final stage circuit that are arranged in the X direction. Thus, the resistors Rs for countermeasure against static electricity are added to each of the gates, sources, and drains of all transistors that are included in the first stage circuit and the final stage circuit. Meanwhile, in a case in which the power supply wires are connected from one side of the peripheral circuit, it is preferable that the resistors Rs for countermeasure against static electricity are added to each of the gates, sources, and drains of all transistors that are included in the first stage circuit or the final stage circuit on a side to which the power supply wires are connected.

In order to realize the resistor Rs for countermeasure against static electricity, for example, using a wire having a resistor, wiring pattern of the peripheral circuit has to be modified. In a case in which an element such as a transistor or a wire connected to the element that is included in the peripheral circuit has disposition (pattern) with complex or high-definition, it is difficult to add a wire for a new countermeasure against static electricity. Thus, the inventors developed a method of adding the resistors Rs for countermeasure against static electricity, using a circuit disposition of the related art of the peripheral circuit. Hereinafter, specific examples will be used. In the examples, transistors that are included in a first stage circuit and a second stage circuit will be described as examples.

### Example 1

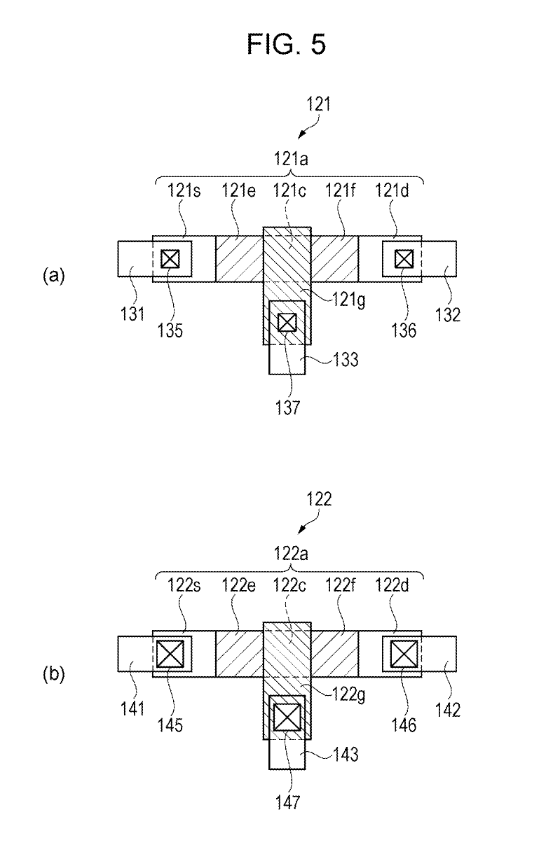

FIG. 5(a) is a schematic plan view illustrating a configuration of a transistor of a first stage circuit of Example 1, and FIG. 5(b) is a schematic plan view illustrating a configuration of a transistor of a second stage circuit of Example 1.

As illustrated in FIG. 5(a), a transistor 121 that is included in an inverter circuit 101s1 of a shift register 101s which is used as the first stage circuit of Example 1 includes a semiconductor layer 121a and a gate electrode 121g. The semiconductor layer 121a is formed from, for example, polysilicon, impurity ions are injected selectively and with different concentrations, and thereby, a channel region 121c, a source region 121s, a lightly doped drain (LDD) region 121e between the channel region 121c and the source region 121s, a drain region 121d, and an LDD region 121f between the channel region 121c and the drain region 121d are formed. That is, the transistor 121 has an LDD structure in which the LDD region 121e is in contact with the source side of the channel region 121c, and the LDD region 121f is in contact with the drain side of the channel region 121c.

A source wire 131 is electrically connected to the source region 121s of the semiconductor layer 121a via a contact section 135. A drain wire 132 is electrically connected to the drain region 121d via a contact section 136. That is, the contact section 135 functions as a source electrode, and the contact section 136 functions as a drain electrode.

In addition, the gate electrode 121g is formed in a position opposing the channel region 121c across a gate insulating film (not illustrated), and the gate electrode 121g is electrically connected to a gate wire 133 via a contact section 137.

As illustrated in FIG. 5(b), a transistor 122 included in an inverter circuit 101s2 of the shift register 101s that is used as a second stage circuit of Example 1 includes a semiconductor layer 122a and a gate electrode 122g. The semiconductor layer 122a is formed from, for example, polysilicon, impurity ions are injected selectively and with different concentrations, and thereby, an LDD structure is formed. Thus, the semiconductor layer 122a includes a source region 122s, an LDD region 122e, a channel region 122c, an LDD region 122f, and a drain region 122d.

A source wire 141 is electrically connected to the source region 122s of the semiconductor layer 122a via a contact section 145. A drain wire 142 is electrically connected to the drain region 122d via a contact section 146. That is, the contact section 145 functions as a source electrode, and the contact section 146 functions as a drain electrode.

In addition, the gate electrode 122g is formed in a position facing the channel region 122c across a gate insulating film (not illustrated), and the gate electrode 122g is electrically connected to a gate wire 143 via a contact section 147.

As illustrated in FIGS. 5A and 5B, the contact sections 135, 136, and 137 of the transistor 121 of the first stage circuit have a smaller planar size than the contact sections 145, 146, and 147 of the transistor 122 of the second stage circuit. For example, the contact sections are contact holes that pass through a gate insulating film or an interlayer insulating film which covers the semiconductor layers 121a and 122a. By coating the inside of the contact hole with a conductive film, an electrical connection is made. For example, the planar shape of the contact sections 135, 136, and 137 of the transistor 121 is a square shape, one side of which has a length of approximately 0.5 μm. In contrast to this, the planar shape of the contact sections 145, 146, and 147 of the transistor 122 is also a square shape, but one side has a length of approximately 1.0 μm. If a conductive film with which the inside of a contact hole is coated is formed from, for example, aluminum (Al) and the semiconductor layers 121a and 122a are formed from polysilicon, connection resistances of the contact sections 135, 136, and 137 become approximately 1250Ω. With respect to this, connection resistances of the contact sections 145, 146, and 147 become approximately 750Ω. That is, the transistor 121 has a configuration in which the resistors Rs of approximately 500Ω for countermeasure against static electricity are added to each of the gate, source, and drain of the transistor 122.

The planar shape of the contact sections 135, 136, 137, 145, 146, and 147 is not limited to a square shape, and for example, may be a round shape.

### Example 2

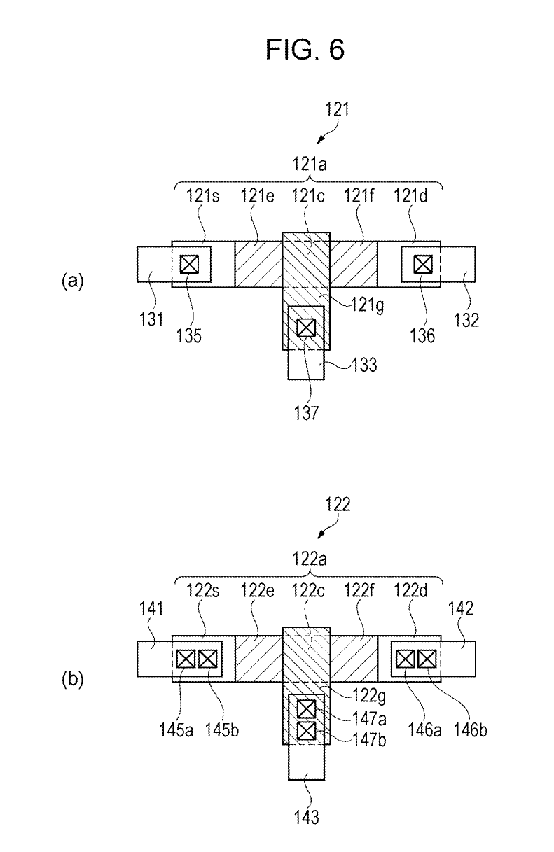

FIG. 6(a) is a schematic plan view illustrating a configuration of a transistor of a first stage circuit of Example 2, and FIG. 6(b) is a schematic plan view illustrating a configuration of a transistor of a second stage circuit of Example 2.

In Example 2, the sizes of contact sections of the transistor of the first stage circuit and the transistor of another circuit (second stage) of a peripheral circuit are set to be the same as each other, and the number of the contact sections are set to be different from each other. Thus, the same symbols or reference numerals are attached to the same configuration as that of Example 1, and detailed description thereof will be omitted.

Specifically, as illustrated in FIG. 6(a), the transistor 121 of the first stage circuit includes, in total, three contact sections that include the contact section 135 which functions as a source electrode, the contact section 136 which functions as a drain electrode, and the contact section 137 which electrically connects together the gate electrode 121g and the gate wire 133.

In contrast to this, the transistor 122 of the second stage circuit includes, in total, six contact sections that include the two contact sections 145a and 145b which function as a source electrode, the two contact sections 146a and 146b which function as a drain electrode, and the two contact sections 147a and 147b which electrically connect together the gate electrode 122g and the gate wire 143.

The two contact sections 145a and 145b are disposed so as to be arranged in an extending direction of the source wire 141. The two contact sections 146a and 146b are disposed so as to be arranged in an extending direction of the drain wire 142. The two contact sections 147a and 147b are disposed so as to be arranged in an extending direction of the gate wire 143.

The planar shape of the contact sections 135, 136, 137, 145a, 145b, 146a, 146b, 147a, and 147b is a square shape, one side of which has a length of approximately 0.5 μm.

Thus, as described in Example 1, if a conductive film that coats the inside of a contact hole is formed from, for example, aluminum (Al) and the semiconductor layers 121a and 122a are formed from polysilicon, connection resistances of the contact sections 135, 136, and 137 become approximately 1250Ω. In contrast to this, the connection resistances of the two contact sections 145a and 145b that functions as a source electrode are approximately 625Ω. The other contact sections that include the contact sections 146a and 146b and the contact sections 147a and 147b are also the same. That is, the transistor 121 of Example 2 has a configuration in which the resistors Rs of approximately 625Ω for countermeasure against static electricity are added to each of the gate, source, and drain of the transistor 122.

The number of contact sections of the transistor 121 and the transistor 122 is not limited to this. If the sizes of the contact sections are equal to each other, the number of the contact sections of the transistor 121 may be smaller than that of the transistor 122.

### Example 3

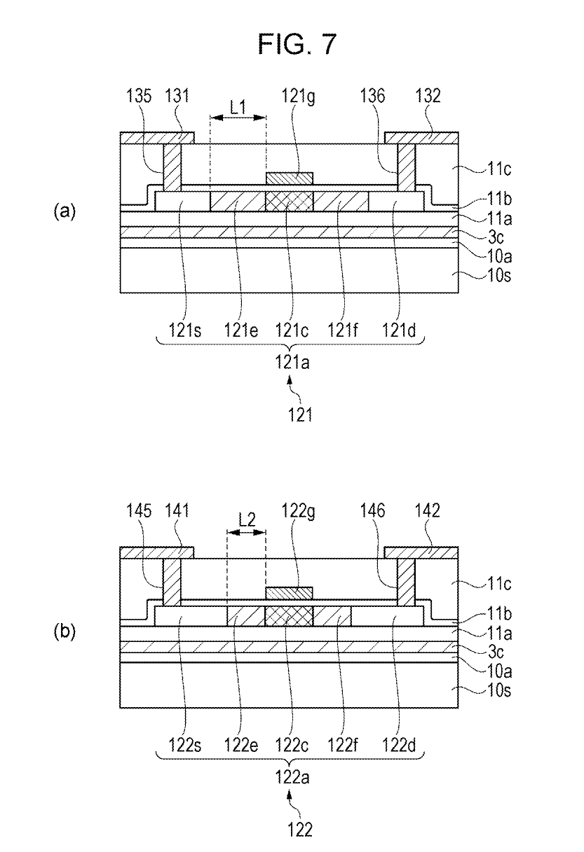

FIG. 7(a) is a schematic plan view illustrating a configuration of a transistor of a first stage circuit of Example 3, and FIG. 7(b) is a schematic plan view illustrating a configuration of a transistor of a second stage circuit of Example 3.

Example 3 uses a resistor Rs for an LDD region of a semiconductor layer of the transistor of the first stage circuit. Thus, the same symbols or reference numerals are attached to the same configuration as that of Example 1, and detailed description thereof will be omitted.

A structure on the base member 10s of the element substrate 10 of the transistor 121 of the first stage circuit and the transistor 122 of the second stage circuit of Example 3 will be described with reference to FIGS. 7A and 7B.

As illustrated in FIG. 7(a), a lower insulating film 10a is formed which covers the base member 10s and is formed from, for example, silicon oxide or the like. A wire 3c with light shielding properties is formed on the lower insulating film 10a. A single metal, such as Al, Ti, Cr, W, Ta, or Mo, an alloy that contains at least one of the single metals, metal silicide, polysilicide, nitride, or materials in which those are stacked can be used for the wire 3c.

A first interlayer insulating film 11a that is formed from, for example, silicon oxide or the like so as to cover the wire 3c is formed, and a semiconductor layer 121a of the transistor 121 is formed in an island shape in a position that overlaps the wire 3c on the first interlayer insulating film 11a. The semiconductor layer 121a is formed from, for example, polysilicon as described above, impurity ions are injected into the semiconductor layer 121a, and an LDD structure that includes the source region 121s, the LDD region 121e, the channel region 121c, the LDD region 121f, and the drain region 121d is formed in the semiconductor layer 121a. The semiconductor layer 121a is disposed on the upper layer of the wire 3c with light shielding properties, and thereby light that is incident from the base member 10s side is shielded by the wire 3c, and a structure which prevents malfunction of the transistor 121 due to the incident light is provided.

A gate insulating film 11b is formed so as to cover the semiconductor layer 121a. Furthermore, a gate electrode 121g is formed in a position opposing the channel region 121c across the gate insulating film 11b.

A second interlayer insulating film 11c that covers the gate electrode 121g and the gate insulating film 11b is formed, and two contact holes that pass through the gate insulating film 11b and the second interlayer insulating film 11c are formed in positions that overlap the source region 121s and the drain region 121d of the semiconductor layer 121a. Then, a conductive film is formed by using a conductive material with light shielding properties such as aluminum (Al) so as to fill the two contact holes and cover the second interlayer insulating film 11c. By patterning the formed conductive film, the contact sections 135 and 136 are formed. In addition, a source wire 131 that is connected to the source region 121s via the contact section 135 is formed. At the same time, a drain wire 132 that is connected to the drain region 121d via the contact section 136 is formed.

As illustrated in FIG. 7(b), a semiconductor layer 122a of the transistor 122 is also formed in an island shape in a position that overlaps the wire 3c, on the first interlayer insulating film 11a of the base member 10s. The semiconductor layer 122a is also formed from, for example, polysilicon as described above, impurity ions are injected into the semiconductor layer 122a, and an LDD structure that includes the source region 122s, the LDD region 122e, the channel region 122c, the LDD region 122f, and the drain region 122d is formed in the semiconductor layer 122a.

In the semiconductor layer 121a of the transistor 121 of the first stage circuit, a length L1 (hereinafter, referred to as LDD length L1) of the LDD region 121e between the channel region 121c and the source region 121s is greater (longer) than a length L2 (hereinafter, referred to as LDD length L2) of the LDD region 122e in the semiconductor layer 122a of the transistor 122 of the second stage circuit. In the present embodiment, the LDD lengths of the LDD region 121e and the LDD region 121f are the same L1. In addition, the LDD lengths of the LDD region 122e and the LDD region 122f are the same L2. The lengths of the LDD regions 121e and 121f of the transistor 121 are greater (longer) than those of the transistor 122, and thereby the LDD regions 121e and 121f can function as the resistors Rs. In addition, Example 3 includes a configuration in which the planar shape of the contact sections 135, 136, and 137 described in Example 1 is small and a configuration in which the length of the LDD regions 121e and 121f is large, and thus, it is possible to further increase the values of the resistors Rs on the source side and the drain side of the transistor 121. Thus, the transistor 121 of the first stage circuit of Example 3 has a configuration in which the resistors Rs for countermeasure against static electricity are added to each of the gate, source, and drain of the transistor 122 of the second stage circuit.

The LDD structure of the transistors 121 and 122 is not limited to this, and may have a configuration in which one LDD region is in contact with the source side or the drain side with respect to the channel region. In addition, a method of setting the LDD region of the transistor 121 of the first stage circuit as the resistors Rs for countermeasure against static electricity is not limited to increasing (lengthening) the length of the LDD region with a low impurity ion concentration. For example, if a dose amount (impurity ion concentration to be injected) of the LDD region of the transistor 121 of the first stage circuit is decreased with respect to the transistor 122, the electrical resistance of the LDD region is increased without a change of the size of the LDD region, and thereby the LDD region can function as the resistor Rs for countermeasure against static electricity.

In Example 1, the resistance value (1250Ω) of the contact sections 135, 136, and 137 in the transistor 121 of the first stage circuit is approximately 1.7 times the resistance value (750Ω) of the contact sections 145, 146, and 147 in the transistor 121 of the second stage circuit.

In Example 2, the resistance value (1250Ω) of the contact sections 135, 136, and 137 in the transistor 121 of the first stage circuit is twice the resistance value (625Ω) of the contact sections 145a, 145b, 146a, 146b, 147a, and 147b in the transistor 121 of the second stage circuit.

It depends on the configuration of the peripheral circuit, but it is preferable that the resistance values of the contact sections 135, 136, and 137 are set in such a manner that a peripheral circuit does not degrade the electrical characteristics of a signal to be originally transferred. Specifically, it is preferable that the resistance value of the resistors Rs which are added to the gate, source, and drain of one of the transistors 121 is approximately 1.25 to 1.5 times the resistance value between itself and the wires to which the gate, source, and drain of the transistor 122 are connected. In a case in which the value is equal to or greater than 1.5 times, it is necessary to confirm the display quality of the liquid crystal device 100.

As described above, the resistors Rs for countermeasure against static electricity have been described by using Example 1 to Example 3, but Example 2 in which the number of contact sections is reduced may be combined with Example 3 in which the LDD regions are set as the resistors Rs.

In addition, as described above, the resistors Rs for countermeasure against static electricity may be added to the transistors that are included in the first stage circuit and/or the final stage circuit of the peripheral circuit to which the power supply wires are connected.

Furthermore, if a tendency for an electrostatic breakdown to easily occur is considered, it is preferable that the resistors Rs are added in series to the source or the drain of a transistor side which is connected to the power supply wires to which the drive potential VDD that is higher than the reference potential VSS is supplied, or to the gate electrode 121g that is opposed to the channel region 121c across the gate insulating film 11b. That is, if the resistors Rs are added in series to at least one of the gate, source, and drain of the transistor 121, it is an effective countermeasure against static electricity.

In addition to this, the peripheral circuit to which the resistors Rs for countermeasure against static electricity are added is not limited to the data line drive circuit 101, and can also be applied to the scan line drive circuit 102, the test circuit 103, the sampling circuit, and the precharge circuit, as described above.

In addition, the data line drive circuit is just an example thereof, and it is needless to say that the invention can be applied to data line drive circuits of other forms.

### Second Embodiment

### Electronic Apparatus

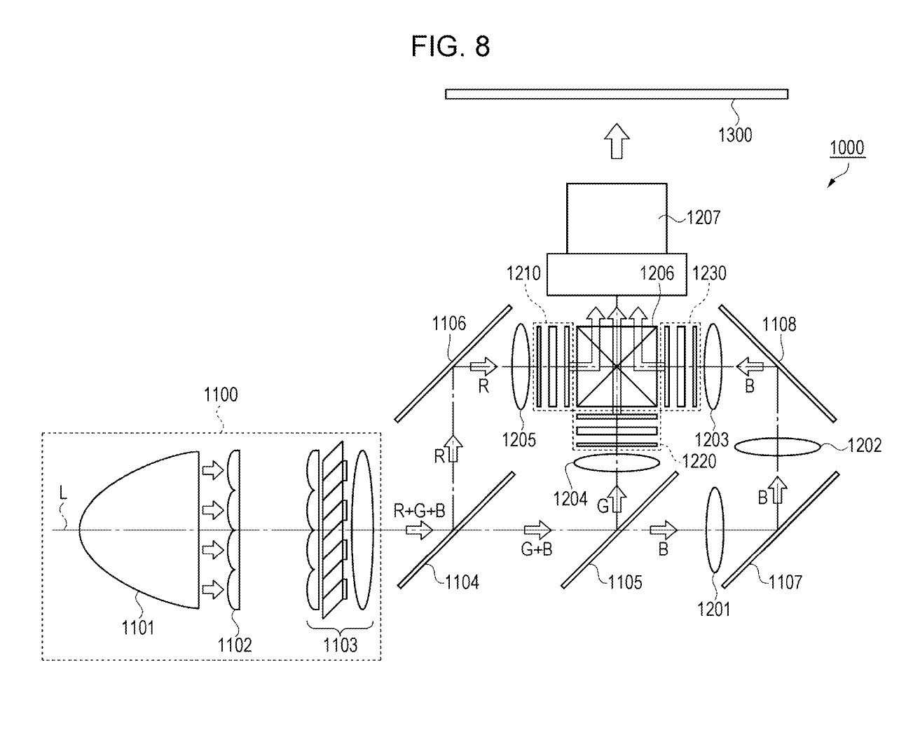

Next, a projection type display device that is used as an electronic apparatus according to a second embodiment will be described with reference to FIG. 8. FIG. 8 is a schematic diagram illustrating a configuration of a projection type display device.

As illustrated in FIG. 8, the projection type display device 1000 that is used as an electronic apparatus according to the present second embodiment includes a polarized light illumination device 1100 that is disposed along a system optical axis L, two dichroic mirrors 1104 and 1105 that are used as light separating elements, three reflecting mirrors 1106, 1107, and 1108, five relay lenses 1201, 1202, 1203, 1204, and 1205, liquid crystal light valves of a transmission type 1210, 1220, and 1230 that are used as three optical modulation units, a cross dichroic prism 1206 that is used as a photosynthesis element, and a projection lens 1207.

The polarized light illumination device 1100 is schematically configured by a lamp unit 1101 that is used as a light source which is configured by a white light source such as an ultrahigh pressure mercury lamp or halogen lamp, an integrator lens 1102, and a polarized light conversion element 1103.

The dichroic mirror 1104 reflects red light (R) and makes green light (G) and blue light (B) pass through, among polarized light flux that is emitted from the polarized light illumination device 1100. The other dichroic mirror 1105 reflects the green light (G) that passes through the dichroic mirror 1104, and makes the blue light (B) pass through.

The red light (R) that is reflected by the dichroic mirror 1104 is reflected by the reflection mirror 1106, and thereafter, is incident on the liquid crystal light valve 1210 via the relay lens 1205.

The green light (G) that is reflected by the dichroic mirror 1105 is incident on the liquid crystal light valve 1220 via the relay lens 1204.

The blue light (B) that passes through the dichroic mirror 1105 is incident on the liquid crystal light valve 1230 via a light guide system that is configured by the three relay lenses 1201, 1202, and 1203, and the two reflection mirrors 1107 and 1108.

The liquid crystal light valves 1210, 1220, and 1230 are respectively disposed so as to face the incident surfaces of each color light of the cross dichroic prism 1206. The colored light that is incident on the liquid crystal light valves 1210, 1220, and 1230 is modulated based on image information (image signal) and is emitted toward the cross dichroic prism 1206. The prism is configured by four rectangular prisms that are bonded to each other, and a dielectric multilayer that reflects red light and a dielectric multilayer that reflects blue light are formed in a cross shape in the inner surface of the prism. Three colored lights are synthesized by the dielectric multilayers, and lights that represent color images are synthesized. The synthesized light is projected onto a screen 1300 by the projection lens 1207 that is a projection optical system, and an image is enlarged and is displayed.

The liquid crystal light valve 1210 is a device to which the liquid crystal device 100 described above is applied. A pair of polarization elements that are disposed in the cross-nicol prism are disposed with a gap on the incident side and emission side of the color light of the liquid crystal device 100. The other liquid crystal light valves 1220 and 1230 are the same as the liquid crystal light valve 1210.

According to the projection type display device 1000, the liquid crystal device 100 having a peripheral circuit to which countermeasure against static electricity is applied is used as the liquid crystal light valves 1210, 1220, and 1230, and thus, it is possible to provide the projection type display device 1000 that has desired electro-optical characteristics and is resistant against static electricity.

The invention is not intended to be limited to the embodiments described above, and may be appropriately modified within the scope that does not depart from the gist or spirit of the invention which is read from the claims and the entire specification. An electro-optical device with such modification and an electronic apparatus to which the electro-optical device is applied are also included in the technical scope of the invention. In addition to the embodiments, various modifications are considered. Hereinafter, description will be made using modification examples.

### Modification Example 1

The data line drive circuit 101 of the liquid crystal device 100 according to the first embodiment is not limited to being formed on the base member 10s of the element substrate 10. For example, the data line drive circuit may be separately fabricated as an IC (integrated circuit) chip, and may be configured to be embedded directly in a terminal section of the element substrate 10 or indirectly via a relay substrate.

### Modification Example 2

An electro-optical device to which the resistors Rs for countermeasure against static electricity in the peripheral circuit according to the first embodiment can be applied is not limited to the projection type liquid crystal device 100. For example, the electro-optical device can also be applied to a reflection type liquid crystal device. In addition, the electro-optical device is not limited to the liquid crystal device, and can also be applied to an organic electroluminescent device that includes a light emission element in each pixel P.

### Modification Example 3

An electronic apparatus to which the liquid crystal device 100 that is used as an electro-optical device is applied is not limited to the projection type display device 1000 according to the third embodiment. For example, the electronic apparatus can be applied to a projection type head-up display (HUD), a direct-view type head mounted display (HMD), an electronic book, a personal computer, a digital still camera, a liquid crystal television, a view finder type or monitor direct view type video recorder, a car navigation system, an electronic notebook, or a display unit of an information terminal device such as POS.

This application claims priority to Japan Patent Application No. 2013-43795 filed Mar. 6, 2013, the entire disclosure of which is hereby incorporated by reference in its entirety.

### REFERENCE SIGNS LIST

100 LIQUID CRYSTAL DEVICE AS ELECTRO-OPTICAL DEVICE
101 DATA LINE DRIVE CIRCUIT AS PERIPHERAL CIRCUIT
102 SCAN LINE DRIVE CIRCUIT AS PERIPHERAL CIRCUIT
103 TEST CIRCUIT AS PERIPHERAL CIRCUIT
121 RESISTOR-ADDED TRANSISTOR
121a SEMICONDUCTOR LAYER
121c CHANNEL REGION
121e,121f LDD REGIONS
131 SOURCE WIRE
132 DRAIN WIRE
133 GATE WIRE
135,136,137 CONTACT SECTION
1000 PROJECTION TYPE DISPLAY DEVICE AS ELECTRONIC APPARATUS
P PIXEL
Rs RESISTOR

1. An electro-optical device comprising:
a pixel circuit; and
a peripheral circuit that drives and controls the pixel circuit,
wherein the peripheral circuit includes a resistor that is added to a transistor which is included in at least one of a first stage circuit and a final stage circuit of the peripheral circuit.

2. The electro-optical device according to claim 1, wherein the resistor is added in series to at least one of positions between a gate of the transistor and a gate wire, between a source of the transistor and a source wire, and between a drain of the transistor and a drain wire.

3. The electro-optical device according to claim 1,
wherein the resistor is a contact section that is provided at least at one of positions between a gate of the transistor and a gate wire, between a source of the transistor and a source wire, and between a drain of the transistor and a drain wire, and
wherein the contact section has a smaller size than that of a transistor that is included in a circuit other than the first stage circuit and the final stage circuit of the peripheral circuit.

4. The electro-optical device according to claim 1
wherein the resistor is a contact section that is provided at least at one of positions between a gate of the transistor and a gate wire, between a source of the transistor and a source wire, and between a drain of the transistor and a drain wire, and
wherein the number of the contact sections is smaller than the number of transistors that is included in a circuit other than the first stage circuit and the final stage circuit of the peripheral circuit.

5. The electro-optical device according to claim 1,
wherein the transistor includes a semiconductor layer that includes a channel region and a lightly doped drain (LDD) region that is in contact with the channel region, and
wherein the resistor is the LDD region, and is longer in LDD length than an LDD region of a transistor that is included in a circuit other than the first stage circuit and the final stage circuit of the peripheral circuit.

6. The electro-optical device according to claim 1
wherein the transistor includes a semiconductor layer that includes a channel region and a lightly doped drain (LDD) region that is in contact with the channel region, and
wherein the resistor is the LDD region, and is smaller in a dose amount of impurity ions than an LDD region of a transistor that is included in a circuit other than the first stage circuit and the final stage circuit of the peripheral circuit.

7. A drive circuit comprising:
a first stage circuit;
a second stage circuit;
a final stage circuit; and
a resistor that is added to a transistor which is included in at least one circuit of the first stage circuit and the final stage circuit.

8. The drive circuit according to claim 7,
wherein the resistor is added to at least one of positions between a gate of the transistor and a gate wire, between a source of the transistor and a source wire, and between a drain of the transistor and a drain wire.

9. The drive circuit according to claim 7,
wherein the resistor is a portion of a resistor of a contact section that is provided at least at one of positions between a gate of the transistor and a gate wire, between a source of the transistor and a source wire, and between a drain of the transistor and a drain wire, and
wherein an area of the contact section is smaller than that of a contact section that is provided between a transistor and a wire which are included in the second stage circuit.

10. The drive circuit according to claim 7,
wherein the resistor is a portion of a resistor of a contact section that is provided at least at one of positions between a gate of the transistor and a gate wire, between a source of the transistor and a source wire, and between a drain of the transistor and a drain wire, and
wherein the number of the contact sections is smaller than the number of contact sections that is provided between a transistor and a wire which are included in the second stage circuit.

11. The drive circuit according to claim 7,
wherein the transistor includes a semiconductor layer that includes a channel region and a lightly doped drain (LDD) region that is in contact with the channel region, and
wherein the resistor is a portion of a resistor of the LDD region, and the LDD region is longer in LDD length than an LDD region of a transistor that is included in the second stage circuit.

12. The drive circuit according to claim 7,
wherein the transistor includes a semiconductor layer that includes a channel region and a lightly doped drain (LDD) region that is in contact with the channel region, and
wherein the resistor is a portion of a resistor of the LDD region, and the LDD region is lower in impurity concentration than an LDD region of a transistor that is included in the second stage circuit.

13. An electronic apparatus comprising:
the electro-optical device according to claim 1.
